(19) United States
(12) Patent Application Publication
(10) Pub. No.: US 2011/0297973 A1
(43) Pub. Date: Dec. 8, 2011

(54) LED WITH AN ADSORPTION PLATE

(76) Inventor: Jae Yong Heo, Seoul (KR)

(21) Appl. No.: 13/202,283

(22) PCT Filed: Feb. 18, 2010
(86) PCT No.: PCT/KR2010/000998

§ 371 Date: Aug. 18, 2011

(30) Foreign Application Priority Data
Feb. 18, 2009 (KR) 10-2009-0013293

(51) Int. Cl. H01L 33/48

(52) U.S. Cl. 257/88; 257/98; 257/99; 257/E33.06

(57) ABSTRACT

The present invention relates to an LED with an adsorption plate attached thereto, and more particularly, to an LED which is covered with a light transmitter made of a light-transmitting material to prevent light scattering and to restrict the light radiation range to the size of the light transmitter. The light transmitter has a thin film light-transmitting portion and a thick film light-transmitting portion to improve visibility at a short distance and at a long distance, and from the front and the side. Further, a user may freely combine LEDs with adsorption plates attached thereto to express words or sentences for advertisements, and may also easily change the words or sentences.

### TECHNICAL FIELD

The present invention relates to an LED assembly having an adsorption plate attached thereto. In particular, the present invention relates to an LED assembly having an adsorption plate attached thereto, for preventing light from scattering and limiting light emission range to the size of a light-permeable part by covering an LED with the light-permeable part made of a material through which light passes, wherein the light-permeable part comprises light-permeable thin and thick parts, so that it is possible to improve visibility at long/short distances and a front/sides of the LED and allow a user to express user's desired contents and easily change the contents at any time by combining a plurality of LED assemblies each having the adsorption plate attached thereto.

### BACKGROUND ART

Various shapes and types of small signboards are mounted to window in a shop for the purpose of providing information on a product for sale or improving a fine view. There exist various kinds of small signboards from a small signboard made by simply printing characters or figures on paper or cloth to a small signboard luxuriously made by using an acrylic plate. A small signboard using light emitting diodes (LEDs) is used among these small sign boards.

However, in the small signboard using LEDs, the LED emits light forward, and hence the glare of intense light occurs due to high brightness when a user views the LED just in front of the LED. Therefore, user's eyes are easily fatigued. Since light emitted from the LED has a property of advancing straight, the light is hardly emitted from sides of the LED, and therefore, it is not easy to recognize the light from the sides of the LED.

Since light emitted from LEDs attached to a small signboard has high brightness, the light of the LEDs is diffusely reflected from window positioned in front of the small board and blurred on the window. Therefore, it is difficult to recognize characters, numbers or figures intended to communicate using the LEDs at the outside of the window.

Accordingly, in a case where characters, numbers or figures are expressed on a small signboard through combination of several LEDs, user's eyes are easily fatigued just in front of the front side of the LEDs due to the glare of intense light, and it is difficult to recognize the shapes of light-permeable parts of the LEDs. Further, since light emitted from the LEDs is not properly emitted from sides of the LEDs, it is not easy to recognize the shapes of the light-permeable parts of the LEDs. Furthermore, the light emitted from the LEDs is diffusely reflected from window. Therefore, it may be difficult to entirely recognize the characters.

In a conventional light emitting device using an LED, the range of light emitted from one LED is relatively narrow because of the front emission of the LED and the straightness of light emitted from the LED, and therefore, visibility at long and short distances is improved using a plurality of LEDs. However, since the plurality of LEDs should be mounted in the light emitting device, the circuit configuration is complicated, and installation and material costs are increased. Further, it is difficult to perform maintenance and repair.

The small signboard made once provides only previously produced contents as information and should make a new small signboard so as to provide another contents, except a case where characters or figures are simply drawn on paper using a marker pen and the paper is then attached to window using a double-faced tape. Therefore, much time and cost are wasted. In a case where an electric signboard is used, its contents can be easily changed, but the production cost of the electric signboard is high priced.

### DISCLOSURE OF INVENTION

### Technical Problem

Accordingly, an object of the present invention is to provide an LED assembly having an adsorption plate attached thereto, for preventing light from scattering and limiting light emission range to the size of a light-permeable part by covering an LED with the light-permeable part which comprises light-permeable thin and thick parts made of a material through which light passes, wherein the light-permeable thin part transmits light a long distance and also eases the glare of intense light directly in front of the front side of the LED, and the light-permeable thick film transmits the light laterally by reflecting a part of the light, which passes through a thick medium, so that it is possible to improve visibility at long/short distances and a front/sides of the LED and allow a user to express user's desired contents and easily change the contents at any time by combining a plurality of LED assemblies each having the adsorption plate attached thereto.

### Technical Solution

According to an aspect of the present invention, there is provided an LED assembly having an adsorption plate attaching thereto, the LED assembly comprising: at least one LED; a light-permeable part configured to surround an emission part of the LED and transmit light of the LED to an outside thereof; the adsorption plate connected to the light-permeable part at an upper part of the light-permeable part and adhered closely to a fixture so as to fix the light-permeable part to the fixture; a cap positioned on a bottom surface of the LED, the cap surrounding a lower portion of the light-permeable part; and a connection part protruded from the cap.

The connection part may be composed of a flexible connection wire and a connection jack.

The connection part may be a connection port fixed to the cap.

The cap may comprise an electric wire groove configured to have the shape of a groove in which an electric wire is accommodated in an inside thereof; the electric wire accommodated in the electric wire groove; and two spiral connection screws respectively configured to connect positive and negative electrodes of LED to positive and negative electrode wires of the electric wire.

A reflection plate may be mounted to the lower part of the light-permeable part.

The light-permeable part may comprise at least one light-permeable thin part of which thickness is thin in the light-permeable part so as to ease the glare of intense light just in front of the LED and to improve visibility at a long distance, and at least one light-permeable thick part of which thickness is thicker than that of the light-permeable thin part in the light permeable part so as to emit the light to sides of the LED by widely diffusing the light of the LED.

The light-permeable thin or thick part may have the shape of a figure, number or character.

The light-permeable thin or thick part may be coated with a color.

The light-permeable thin or thick part may be made through combination of at least one of transparent, translucent and opaque materials.

The LED assembly may further comprise a support platform positioned beneath the LED and adhered closely to a side of the light-permeable part.

The diameter of the support platform may be greater than that of the LED, and a protection wall for protecting the LED may be mounted around the LED.

A convex lens part surrounding the LED may be formed at the outside of the LED, a lower part of the convex lens part may be coupled to the cap, a thin wall may be formed along a side of the LED from a top of the cap, and a convex lens may be formed above the LED.

A polycarbonate layer may be additionally attached to the upper part of the light-permeable part.

A diffusion layer may be additionally attached at a lower part of the light-permeable part facing the top of the LED.

The diffusion layer may be crystal.

At least one air exhaustion groove or embossing may be formed at the side surface of the light-permeable part.

The adsorption plate and the light-permeable part may be separated from each other, and the light-permeable part may be coupled to the adsorption plate.

A power source for supplying power to the LED may be at least one of a battery, an AC power source, a DC power source, a solar cell and a hybrid.

The light-permeable part may be made of at least one of glass, plastic, silicon, latex, rubber, urethane, resin, epoxy resin, polycarbonate and polymer.

According to another aspect of the present invention, there is provided a plurality of LED assemblies having adsorption plates attached thereto, combined with one another so as to express a character or figure, wherein the LED assemblies comprises: at least one LED; light-permeable parts each surrounding an emission part of the LED and transmitting light of the LED to the outside thereof; caps each positioned on a bottom surface the LED so as to surround an opened part of the light permeable part; connection parts respectively protruded from the caps positioned at both ends of the LED assemblies; and connection wires each protruded from the cap of an LED assembly and connected to the cap of an adjacent LED assembly so as to connect the plurality of LED assemblies to one another, wherein the adsorption plate connected to the light-permeable part at an upper part of the light-permeable part and adhered closely to a fixture so as to fix the LED assemblies to the fixture is attached to at least one of the light-permeable parts.

The LED assemblies having the adsorption plates attached thereto may be attached at a predetermined interval to the fixture.

According to still another aspect of the present invention, there is provided an LED assembly having an adsorption plate attaching thereto, the LED assembly comprising: first and second LEDs respectively attached to both surfaces of a fixing part about the fixing part;

first and second light-permeable parts respectively configured to surround the first and second LEDs and transmit light of the first and second LEDs to outsides thereof; the adsorption plate connected to the first light-permeable part at an edge of a top of the first light-permeable part and adhered closely to a fixture so as to fix the first light-permeable part to the fixture; and a connection part protruded from the fixing part.

According to still another aspect of the present invention, there is provided plurality of LED assemblies each having an adsorption plate attached thereto, respectively inserted into a plurality of grooves formed at a predetermined interval in a cloth or film on which a specific content is printed, wherein each of the LED assemblies comprises: at least one LED; a light-permeable part configured to surround an emission part of the LED and transmit light of the LED to an outside thereof; the adsorption plate connected to the light-permeable part at an upper part of the light-permeable part and adhered closely to a fixture so as to fix the light-permeable part to the fixture; a cap positioned on a bottom surface of the LED, the cap surrounding a lower portion of the light-permeable part; and a connection part protruded from the cap.

According to still another aspect of the present invention, there is provided plurality of LED assemblies each having an adsorption plate attached thereto, attached at a predetermined interval on an UV protection film, wherein each of the LED assemblies comprises: at least one LED; a light-permeable part configured to surround an emission part of the LED and transmit light of the LED to an outside thereof; the adsorption plate connected to the light-permeable part at an upper part of the light-permeable part and adhered closely to a fixture so as to fix the light-permeable part to the fixture; a cap positioned on a bottom surface of the LED, the cap surrounding a lower portion of the light-permeable part; and a connection part protruded from the cap.

### Advantageous Effects

According to the present invention, the LED assembly having the adsorption plate attached thereto employs a specifically produced light-permeable part, so that the visibility at long/short distances and front/sides is improved, thereby maximizing information distribution, fine view and advertisement effect. Further, the LED assembly having the adsorption plate attached thereto enables a user to express user's desired contents and easily change the contents at any time as the user desires. Furthermore, any character or figure can be easily expressed by connecting a plurality of LED assemblies each having the adsorption plate attached thereto.

Unlike the conventional electric signboard, initial mounting cost is hardly used, and the change in contents can be easily performed without using additional cost.

Since the LED assembly is used, the power consumption can be minimized, and the LED assembly can be almost semi-permanently used.

The LED assembly is used so as to ensure visibility of pole signs for public relations in a business place or shopping street, so that figures or characters can be effectively provided using flashes emitted from the LED assembly. Further, the LED having a small and slim adsorption plate attached thereto is used, so that interior production for display and production for advertisement can be performed by effective using a limited space of window.

### BRIEF DESCRIPTION OF DRAWINGS

FIG. 1 is a schematic view of an LED assembly having an adsorption plate attached thereto according to the present invention.

FIG. 2 is a schematic view of the LED assembly having the adsorption plate attached thereto when an emission part of an LED is small according to present invention.

FIG. 3 is a schematic view showing a state that the LED assembly having the adsorption plate attached thereto is fixed to a fixing body according to the present invention.

FIG. 4 is a sectional view showing another embodiment of a connection part.

FIG. 5 is a schematic view of the LED assembly having the adsorption plate attached thereto, which has a hemispherical light-permeable part.

FIG. 6 shows sectional views when the LED assembly having the adsorption plate attached thereto is viewed from the top thereof according to the present invention.

FIG. 7 is a schematic view of the LED assembly having the adsorption plate attached thereto, in which a convex lens part is additionally formed.

FIG. 8 is a sectional view of the LED assembly having the adsorption plate attached thereto, to which a polycarbonate layer is attached.

FIG. 9 is a sectional view of the LED assembly having the adsorption plate attached thereto, in which a diffusion layer is mounted.

FIG. 10 is a sectional view of the LED assembly having the adsorption plate attached thereto, in which a support platform is additionally mounted.

FIG. 11 is a sectional view of the LED assembly having the adsorption plate attached thereto, in which a protection wall is additionally mounted.

FIG. 12 is a sectional view of the LED assembly having the adsorption plate having two air exhaustion grooves formed therein.

FIG. 13 is a sectional view taken along line A-A of FIG. 12.

FIG. 14 is a sectional view of the LED assembly having an embossing form therein.

FIG. 15 is a sectional view of the LED assembly having the adsorption plate attached thereto, in which a reflection plate is mounted.

FIG. 16 shows embodiments in which a plurality of LED assemblies having adsorption plates attached thereto are combined.

FIG. 17 is a schematic view of the plurality of LED assemblies each having the adsorption plate attached thereto, to which an attachment plate is mounted. FIG. 18 is a schematic view showing another embodiment of the LED assembly having the adsorption plate attached thereto according to the present invention.

FIGS. 19 to 22 are views showing applications of the LED assembly having the adsorption plate attached thereto according to the present invention.

FIG. 23 is a schematic view of a ‘ [symbol] ’-shaped attachment plate.

FIG. 24 is a schematic view of the adsorption plate having a coupler mounted thereto.

FIGS. 25 and 26 are plan and side views of the LED assembly having the adsorption plate attached thereto, which has a cap capable of fixing the LED assembly as occasion demands while moving along an electric wire according to the present invention.

### MODE FOR INVENTION

The present invention now will be described more fully hereinafter with reference to the accompanying drawings, in which embodiments of the invention are shown. This invention should not be construed as limited to the embodiments set forth herein. Rather, these embodiments are provided so that this disclosure will be thorough and complete, and will fully convey the scope of the invention to those skilled in the art.

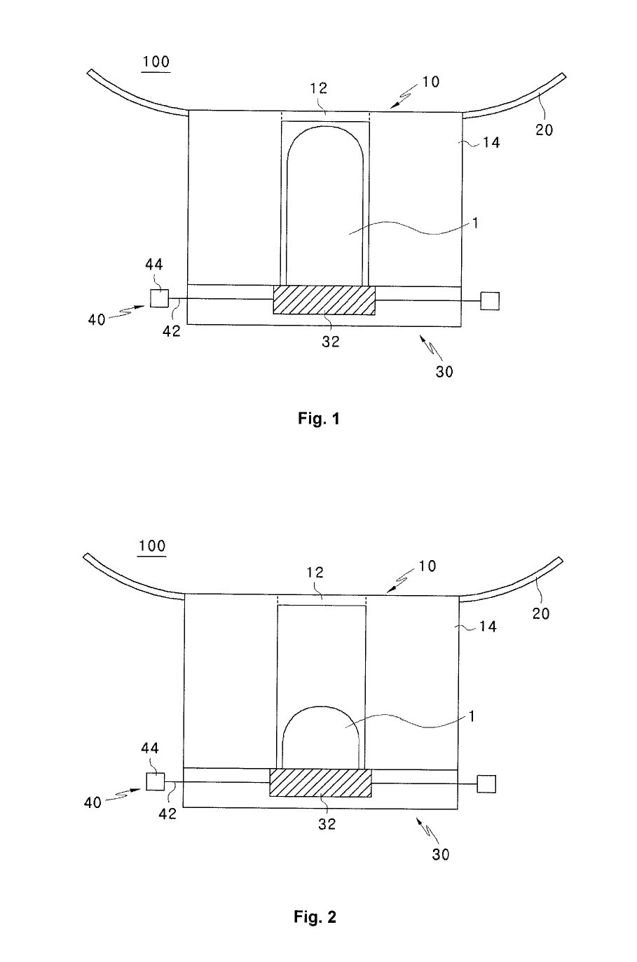

An LED assembly having an adsorption plate attached thereto means one formed by covering a transparent or translucent body through which light can pass over the outside of a luminous body. Although only one LED assembly having an adsorption plate attached thereto may be used, characters, numbers or figures are generally expressed by combining a plurality of LED assemblies each having an adsorption plate attached thereto. FIG. 1 is a schematic view of an LED assembly having an adsorption plate attached thereto according to the present invention. As shown in FIG. 1, the LED assembly 100 according to the present invention comprises an LED 1, a light-permeable part 10, an adsorption plate 20, a cap 30 and connection parts 40. Hereinafter, these parts will be described.

The shape of the LED used in the present invention is not particularly limited. For example, the emission part of the LED may be long as shown in FIG. 1, and the emission part of the LED may be short as shown in FIG. 2. In a case where the emission part of the LED is short as shown in FIG. 2, the brightness at sides of the LED may be more intense as compared with FIG. 1. Further, in a case where the emission part of the LED is short as shown in FIG. 2, the shape of the light-permeable part may be changed depending on the shape of the emission part of the LED. In addition, it will be apparent that an LED of which emission part has a short but wide shape and an LED having a round shape may be applied to the present invention.

The number of LEDs used in the present invention is at least one. Here, the number of LEDs is not particularly limited. In a case where a plurality of LEDs are mounted in the LED assembly, the LEDs having different colors may be mounted in the LED assembly. Further, the LEDs may be mounted at different angles from one another in the LED assembly. This is provided to improve visibility at various angles in consideration of the straightness of light emitted from the LEDs.

The light-permeable part 10 surrounds the emission part of the LED 1 and transmits light of the LED 1 to the outside thereof. The light-permeable part has a flat bottom surface. The light-permeable part 10 prevents light from scattering and limits light emission range to the size of the light-permeable part, so as to increase the degree of concentration of light, to reflect various expressions of light according to the shape of the light-permeable part, and to enable several colors, shapes and brightnesses to be expressed in one LED assembly. Since the light-permeable part 10 surrounds the emission part of the LED 1, the light-permeable part functions to protect the LED 1 from an external impact applied to the LED1. Light emitted from the LED 1 is emitted to the outside of the LED assembly through the light-permeable part 10. While passing through the light-permeable part 10, the light is reflected, diffracted and the like.

The structure of the light-permeable part 10 is not particularly limited. However, the light-permeable part has a space capable of accommodating the LED 1 in the inside thereof, and a lower part of the light-permeable part, into which the LED 1 is inserted, is opened. Since the light-permeable part 10 is also used as an upholding means when the adsorption plate 20 is attached/detached, the light-permeable part is necessarily formed only in one direction of the adsorption plate 20.

The adsorption plate 20 corresponds to a fixing means for fixing the LED assembly having the adsorption plate attached thereto according to the present invention to a glass or flat fixture made of a transparent or translucent material through which light can pass. The fixing means is not particularly limited. However, in the present invention, the adsorption plate 20 is used as the fixing means, so that anyone can easily attach/detach the LED assembly 100 to/from the fixture. Thus, the arrangement of LED assemblies each having an adsorption plate attached thereto can be changed as occasion demands, and accordingly, contents intended to communicate can be easily and simply changed using the LED assemblies each having the adsorption plate attached thereto. The adsorption plate 20 has a shape connected to the light-permeable part 10 at an edge of a top of the light-permeable part 10 or at the top of the light-permeable part 10. The adsorption plate is adhered closely to a fixture 90 such as glass so that the light-permeable part 10 is fixed to the fixture 90. FIG. 3 is a schematic view showing a state that the LED assembly having the adsorption plate attached thereto is fixed to the fixture according to the present invention.

The adsorption plate 20 may be made of a material having an excellent adhesive force so that the LED assembly having the adsorption plate attached thereto according to the present invention can be easily attached to the glass or fixture through which light can pass. Preferably, the light-permeable part 10 and the adsorption plate 20 are made of the same material capable of being easily attached to the fixture. The adsorption plate 20 is preferably made of a transparent material so that all light radiated from a light-permeable thick part 14 is radiated to the outside, except a case where the adsorption plate necessarily blocks light for a specific purpose. More preferably, the adsorption plate is made of silicon, in consideration of transparency, adhesion and modability.

The cap 30 is positioned on a bottom surface of the LED assembly, and corresponds to a stopper for surrounding a lower part of the light-permeable part, which comprises the opened part. An electric wire for supply power to the LED 1 is connected to the LED 1 in the inside of the cap 30, and a PCB substrate 32 may be positioned at this part as occasion demands. That is, the electric wire serves as a connector.

The shape of the cap is not particularly limited. However, the cap preferably has a shape that enables fixing the LED assembly having the adsorption plate attached thereto according to the present invention to be fixed while moving along the electric wire 38 as occasion demands.

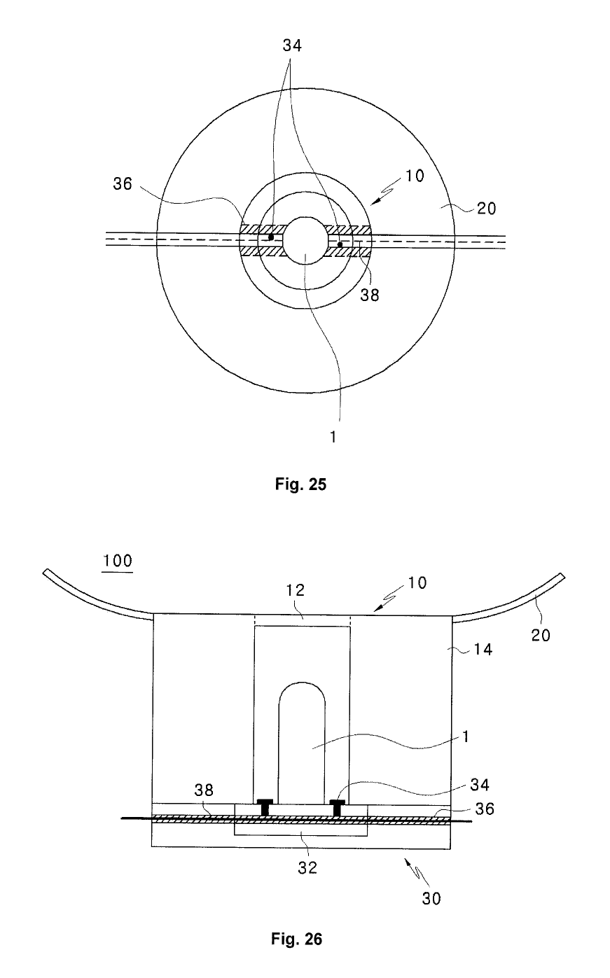

FIGS. 25 and 26 are plan and side views of the LED assembly having the adsorption plate attached thereto, which has a cap capable of fixing the LED assembly as occasion demands while moving along an electric wire according to the present invention. As shown in FIGS. 25 and 26, the cap 30 comprises an electric wire groove 36 having the shape of a groove in which the electric wire 38 is accommodated, the electric wire 38 accommodated in the electric wire groove 36, and two spiral connection screws 34 for respectively connecting positive and negative electrodes of the PCB substrate 32 to positive and negative wires of the electric wire.

If the electric wire 38 accommodated in the electric wire groove 36 is moved by unscrewing the connection screws 34 and the connection screws 34 are gain screwed, a sharp part at an end of each of the connection screws 34 passes through the electric wire 38. Thus, the electric wire 38 is electrically connected to the LED assembly through the connection screws 34. Accordingly, an unnecessary wire does not remain in the middle of the LED assembly having the suction part attached thereto, so that it is possible to have an externally fine view and prevent an electric fault.

The connection parts 40 are parts connected to the electric wire in the inside of the cap so as to be respectively protruded to outsides of the LED assembly through both sides of the cap 30. The connection part 40 may be connected to a connection part of another LED assembly having an adsorption plate attached thereto, or may be connected to an external power supply (not shown).

Each of the connection parts 40 may be composed of a flexible connection wire 42 protruded to both the sides of the cap and a connection jack 44 connected to the flexible connection wire. The flexible connection wire 42 has a length to a certain extent so that it can be connected to a connection part of another LED assembly having an adsorption plate attached thereto. The flexible connection wire 42 may made and sold to have various lengths. The connection jack 44 is a part connected to a connection jack of another LED assembly having an adsorption plate attached thereto. Since the arrangement of the LED assemblies each having the adsorption plate attached thereto according to the present invention is easily changed as occasion demands, the connection jack 44 can be simply connected and separated. For example, two connection jacks in an LED assembly having a suction attached thereto are configured as female and male connection jacks, respectively. The female and male connection jacks are connected to female and male connection jacks of another LED having an adsorption plate attached thereto.

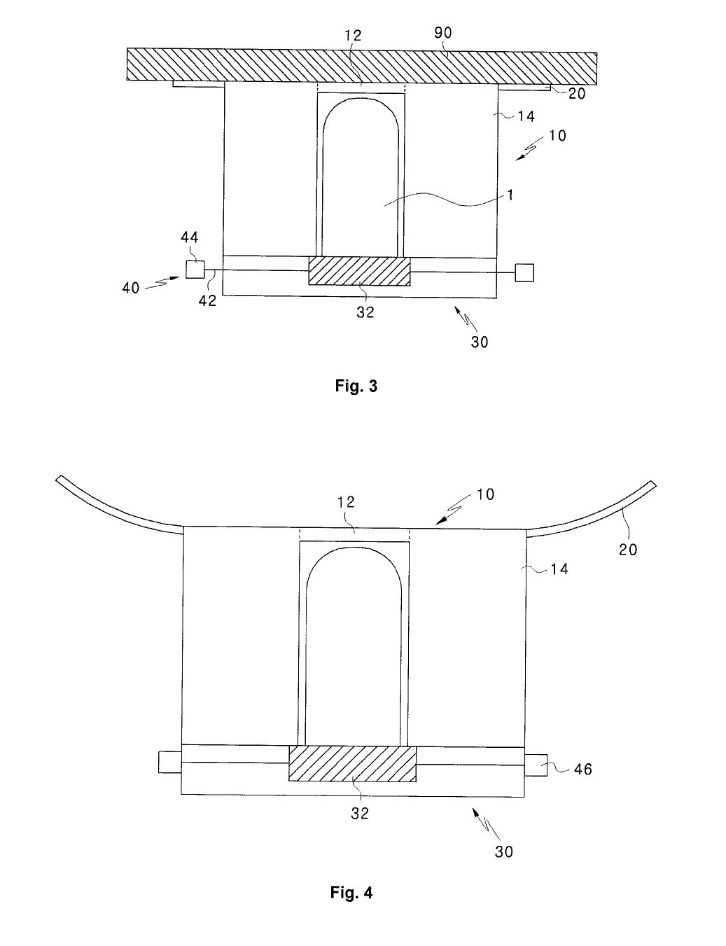

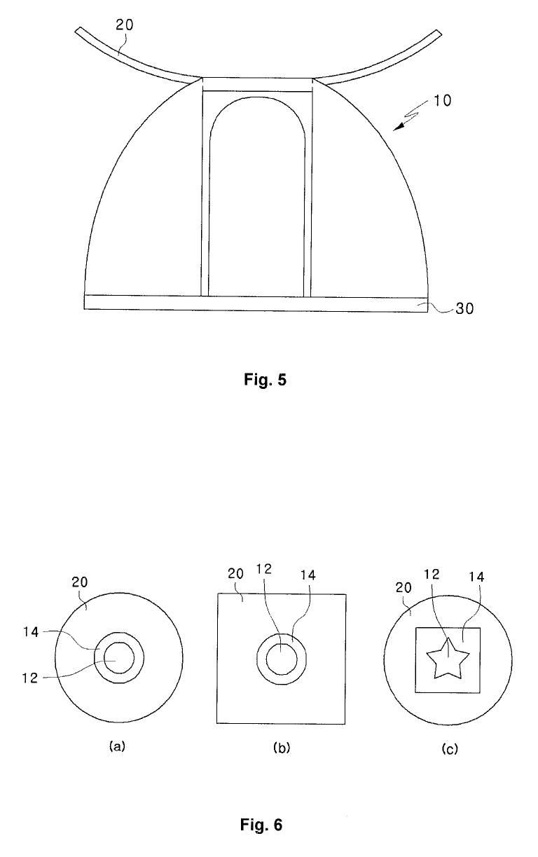

FIG. 4 is a sectional view showing another embodiment of the connection part. As shown in FIG. 4, the connection part 40 has the shape of a connection port 46 fixed to the cap. In this case, the connection port can be used when the plurality of LED assemblies having the adsorption plate attached thereto according to the present invention are connected adjacent to one another. The connection port 46 is used as a product having the same concept as the connection jack 44.

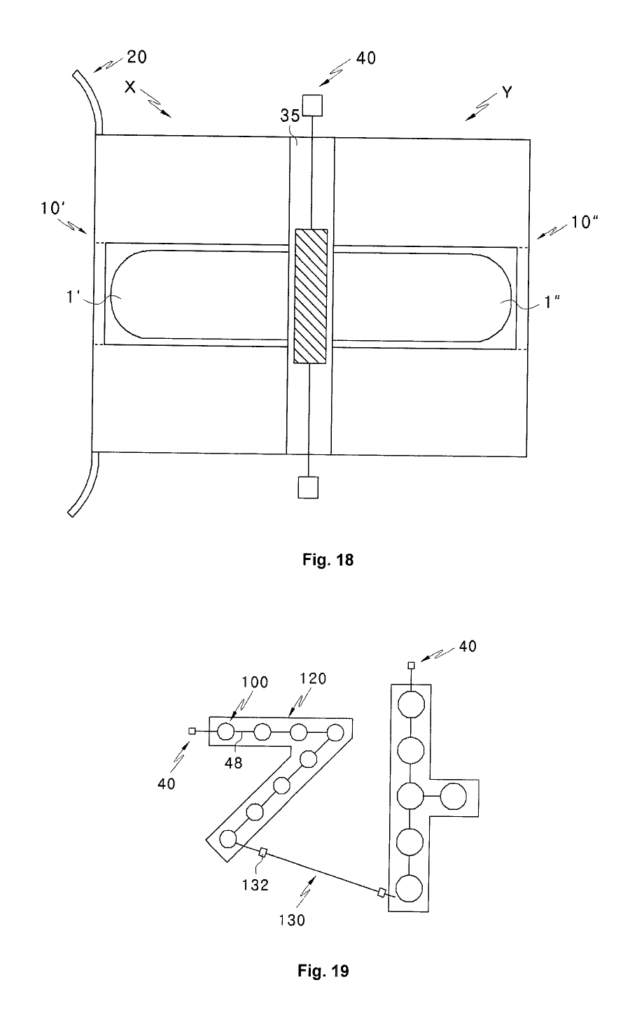

In a case where two LED assemblies each having an adsorption plate attached thereto, which are distant from each other, are connected to each other, an additional connection wire may be used in the middle between the two LED assemblies. Here, the additional connection wire has female and male connection jacks respectively positioned at both ends thereof. The additional connection wire is shown in FIG. 19. In FIG. 19, an additional connection wire 130 has connection jacks 132 respectively positioned at both ends thereof, and is connected to the connection part 40 of the LED assembly having the adsorption plate attached thereto.

In the present invention, the light-permeable part 10 is preferably composed of at least one light-permeable thin part 12 and at least one light-permeable thick part 14.

The light-permeable thin part 12 is a thin part of the light permeable part so as to cast the light of the LED 1 up to a long distance, particularly to ease the glare of intense light just in front of the LED. The light-permeable thick part 14 is a part thicker than the light-permeable thin part 12 in the light-permeable part so as to highlight the shape of the light-permeable part by widely spreading the light of the LED 1 so that light is easily recognized even at sides of the LED 1. In the light-permeable thin part 12, the thickness of a medium through which the light of LED 1 passes is thin, and therefore, almost of the light passes through the light-permeable thin part without loss of energy. Thus, people at a relatively long distance can recognize the light emitted from the light-permeable thin part 12. Further, a thin film exists in the light-permeable thin part 12, and therefore, it is possible to ease the glare of intense light just in front of the front side of the LED.

The thickness of the light-permeable thin part 12 is changed depending on the brightness of the LED mounted in the LED assembly. In a general LED, the thickness of the light-permeable thin part is preferably 0.1 to 10 mm. If the thickness of the light-permeable thin part is less than 0.1 mm, the glare of intense light occurs just in front of the LED. If the thickness of the light-permeable thin part exceeds 10 mm, it is difficult to cast light of the LED up to a long distance because the light is interrupted by the light-permeable part.

The light-permeable thin part 12 casts light to a long distance and ease the glare of intense light just in front of the LED, thereby improving the entire visibility of the LED assembly.

The light-permeable thin part 12 may be formed by making a hole in the inside of the light-permeable part 10 so that the light-permeable part with the hole is thinner than its surroundings or by forming a part from which light is intensely emitted on the outer surface of the light-permeable part to be thinner than its surroundings.

The light-permeable thick part 14 is a part thicker than the light-permeable thin part 12 in the light-permeable part. Since a medium of the light-permeable thick part is thick, a part of the light passing through the medium is reflected in the inside of the light-permeable thick part so that the light is spread throughout the entire of the light-permeable thick part 14 and emitted to the outside of the light-permeable part. Thus, the light emitted from the light-permeable part 14 is darker than that emitted from the light-permeable thin part 12, but is entirely spread, so that it is possible to recognize the shape of the light-permeable part not only in front of the front side of the LED 1 but also at sides of the LED 1.

Since the light-permeable part, particularly the light-permeable thick part exists, intense light of the LED is primarily diffused by the light-permeable part, and thus the brightness of the light in window is relatively lowered, thereby preventing blur of light due to diffused reflection of the light in the window.

As a result, the light emitted from the light-permeable thin part 12 is casted in a direction of the front side of the LED 1 up to a long distance, so that it is possible to enable people at the long distance to easily recognize the light and to ease the glare of intense light just in front of the front side of the LED. Accordingly, it is possible to recognize the light of the LED 1 at a short distance, particularly just in front of the LED, without the fatigue of eyes. The light emitted from the light-permeable part 14 is also emitted to the sides of the LED 1, so that people can easily recognize the shape of the light-permeable part event at the sides of the LED 1. Further, it is possible to prevent the blur of light, caused by window, thereby improving the shapability of the LED assembly. The light emitted from the light-permeable thin part 12 is bright, and the light emitted from the light-permeable thick part 14 is gentle so that the light-permeable thin and thick parts 12 and 14 are harmonized, thereby obtaining a remarkable visual effect.

The thickness of the light-permeable thick part 14 is not particularly limited. However, the light-permeable thick part is preferably 1.5 to 20 times thicker than the light-permeable thin part 12 so that light is emitted to the sides of the LED. If the thickness of the light-permeable thick part exceeds 20 times, the amount of the light emitted to the outside is too small.

The position of each of the light-permeable thin and thick parts 12 and 14 is not particularly limited. However, the light-permeable thin part 12 is preferably formed at the front side that is a direction in which the light of LED 1 is most intensely emitted, in consideration of the straightness of light, so that the light emitted from the light-permeable thin part is casted up to a long distance. The light-permeable thick part 14 is preferably mounted around the light-permeable thin part 12.

The number of each of the light-permeable thin and thick parts 12 and 14 is not particularly limited, and several light-permeable thin and thick parts 12 and 14 may be formed as occasion demands.

The entire shape of the light-permeable part 10 is not particularly limited. In FIG. 1, the light-permeable part has a tetrahedral shape, but may have various three-dimensional shapes such as trihedral, pentahedral, hexahedral and hemispheric shapes. FIG. 5 shows a light-permeable part having a hemispherical shape as an example of various three-dimensional shapes.

When being viewed from the top, the shape of each of the adsorption plate 20, the light-permeable thin part 12 and the light-permeable thick part 14 is not particularly limited. The shape of each of the light-permeable thin and thick parts is generally a circle, but may be the shape of a specific figure or character including a star, a triangle, a square, an animal pattern, a person's figure, a character pattern, and the like. In this case, the shape of a figure or character formed in the light-permeable thin or thick part 12 or 14 can be recognized from the outside. FIG. 6 shows sectional views when the LED assembly having the adsorption plate attached thereto is viewed from the top thereof according to the present invention, which illustrates the adsorption plate 20, the light-permeable thin part 12 and the light-permeable thick part 14, having various shapes.

The light-permeable thin or thick part 12 or 14 may be coated with a color so as to emphasize the visible effect of the LED assembly. Here, the light-permeable thin and thick parts 12 and 14 may be coated with the same color or different colors. The light-permeable thin and thick parts 12 and 14 may be simultaneously coated with several colors. Only the outer parts of the light-permeable thin and thick parts 12 and 14 may be coated with a color. Light emitted from one LED may be variously expressed by allowing the colors of the LED and the light-permeable part to be identical to or different from each other.

The light-permeable thin or thick part 12 or 14 is made by combining at least one of transparent, translucent or opaque materials, so that light emitted from the LED can be variously expressed.

The material of the light-permeable part 10 is not particularly limited, and may be a moldable and permeable material. For example, the material of the light-permeable part may be glass, plastic, silicon, latex, rubber, urethane, resin, epoxy resin, polycarbonate, polymer, or the like. Among these materials, the silicon with excellent moldability or the polycarbonate with excellent light diffusion is most preferably used.

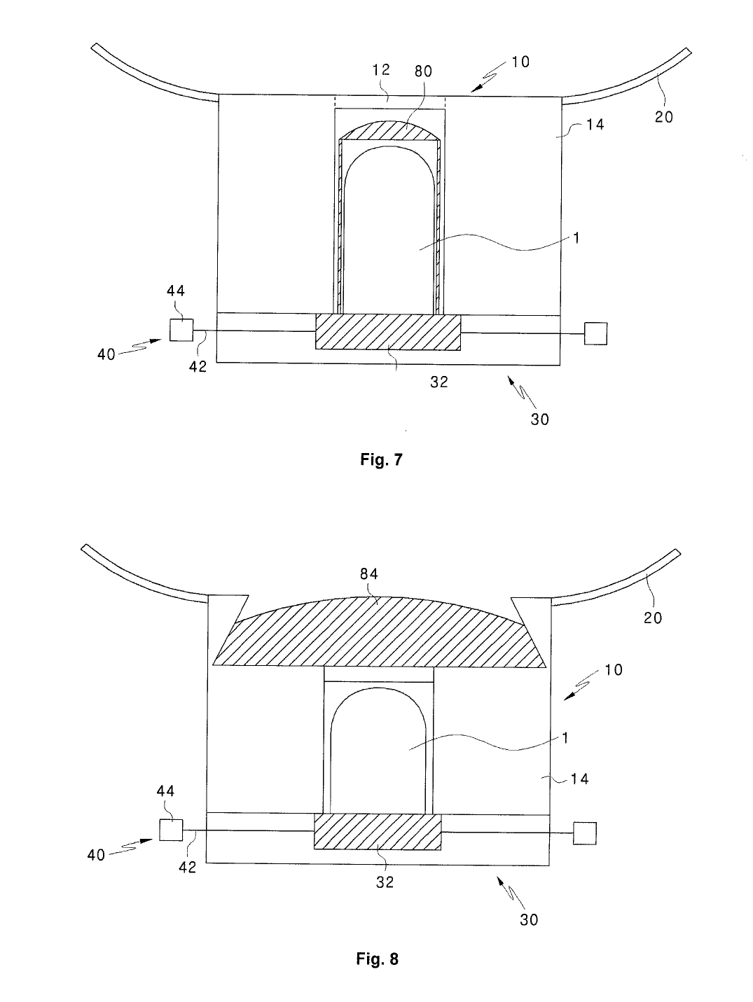

In order to improve visibility at long and short distances, a convex lens part may be additionally formed in the LED assembly having the adsorption plate attached thereto according to the present invention. FIG. 7 is a schematic view of the LED assembly having the adsorption plate attached thereto, in which a convex lens part is additionally formed. The convex lens part 80 surrounds the LED 1, and a lower part of the convex lens part 80 is coupled to the cap 30. A thin wall is formed along a side of the LED 1 from a top of the cap 30, and a convex lens is formed above the LED 1. Light emitted from the LED 1 is primarily diffused broadly in the convex lens part 80 and then secondarily diffused more broadly by the light-permeable part 10 positioned at the outside of the convex lens part 80. Unlike FIG. 7, both sides of the convex lens part may be convex.

In the LED assembly having the adsorption plate attached thereto according to the present invention, a polycarbonate layer may be additionally attached to an upper part of the light-permeable part so as to improve visibility. Since the polycarbonate layer has high diffusivity of light and high permeability of visible light, the polycarbonate layer radiates light with a very stable feeling. The light primarily diffused through the light-permeable part is changed into light with a stable feeling while being secondarily diffused through the polycarbonate layer, so that the visibility is entirely improved. FIG. 8 is a sectional view of the LED assembly having the adsorption plate attached thereto, to which a polycarbonate layer is attached. As shown in FIG. 8, the polycarbonate layer 84 is attached to an upper portion of the light-permeable part 10. The shape of the attached polycarbonate layer 84 is not particularly limited, but an upper portion of the polycarbonate layer is preferably formed in the shape of a convex lens for the purpose of diffusion of light. The method of attaching the polycarbonate layer 84 to the light-permeable part is not particularly limited. However, the polycarbonate layer 84 may be simply attached to the light-permeable part by inserting the polycarbonate layer into a groove formed by engraving the upper part of the light-permeable part.

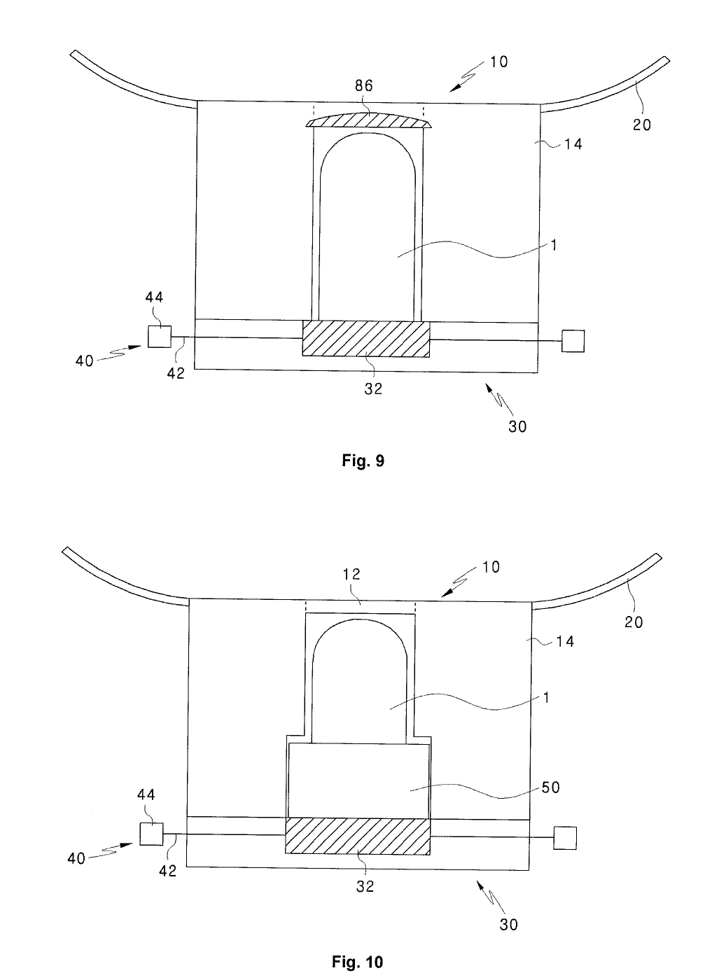

In the LED assembly having the adsorption plate attached thereto according to the present invention, a diffusion layer may be additionally attached at a lower part of the light-permeable part facing the top of the LED so as to broadly diffuse light emitted from the LED. FIG. 9 is a sectional view of the LED assembly having the adsorption plate attached thereto, in which a diffusion layer is mounted. The diffusion layer 86 is made of a material capable of diffusing light as broad as possible. Particularly, the diffusion layer is preferably made of crystal so as to induce diffused reflection. Light primarily diffused by the diffused reflection induced by the diffusion layer 86 is more broadly diffused while passing through the light-permeable part 10, so that the light emission range of the LED assembly having the suction part attached thereto is entirely broadened. The method of attaching the diffusion layer 86 to the light-permeable part 10 is not particularly limited. However, the diffusion layer 86 may be simply attached to the light-permeable part by inserting the diffusion layer into a groove formed in the light-permeable part.

In the LED assembly having the adsorption plate attached thereto according to the present invention, the light permeable part 10 and the LED may be integrally formed or may be separated from each other. In a case where the LED 1 and the light-permeable part 10 are separated from each other, the light-permeable part 10 can be used as it is, when it is necessary to change the color of the LED. In this case, the LED 1 is coupled to the light-permeable part 10 by inserting the LED into the inside of the light-permeable part.

A support platform 50 may be mounted to the bottom of the LED 1 so as to reinforcing the strength of the coupling between the LED and the light-permeable part. The support platform 50 is a part that is completely adhered closely to the light-permeable part 10 so as to allow the LED 1 to be completely fixed in the inside of the light-permeable part 10 and to prevent damage caused by vibration of the LED 1. FIG. 10 is a sectional view of the LED assembly having the adsorption plate attached thereto, in which a support platform is additionally mounted. As shown in FIG. 10, the support platform 50 is completely adhered closely to a side surface of the light-permeable part 10.

FIG. 11 is a sectional view of the LED assembly having the adsorption plate attached thereto, in which a protection wall is additionally mounted. As shown in FIG. 11, the diameter of the support platform 50 is greater than that of the LED 1, and a protection wall 52 for protecting the LED 1 may be mounted around the LED 1. In a case where the LED assembly according to the present invention is used at a part such as a floor on which the LED 1 can be easily damaged, the protection wall 52 is formed in a circular shape around the LED 1 so as to prevent the LED 1 from being easily damaged. Here, the protection wall 52 does not necessarily surround the entire circumference of the LED 1.

In a case where the LED part and the light-permeable part 10 separated from each other are fixed to the fixture 90 using the rear or front insertion method, the LED part and the light-permeable part 10 may be separated from each other in the long-term use of the LED assembly because air in an inside of the light-permeable part 10 into which of the LED part is inserted is compressed in the process of inserting the LED part into the light-permeable part 10. In the present invention, to solve such a problem, an air exhaustion means may be formed in the inside of the light-permeable part.

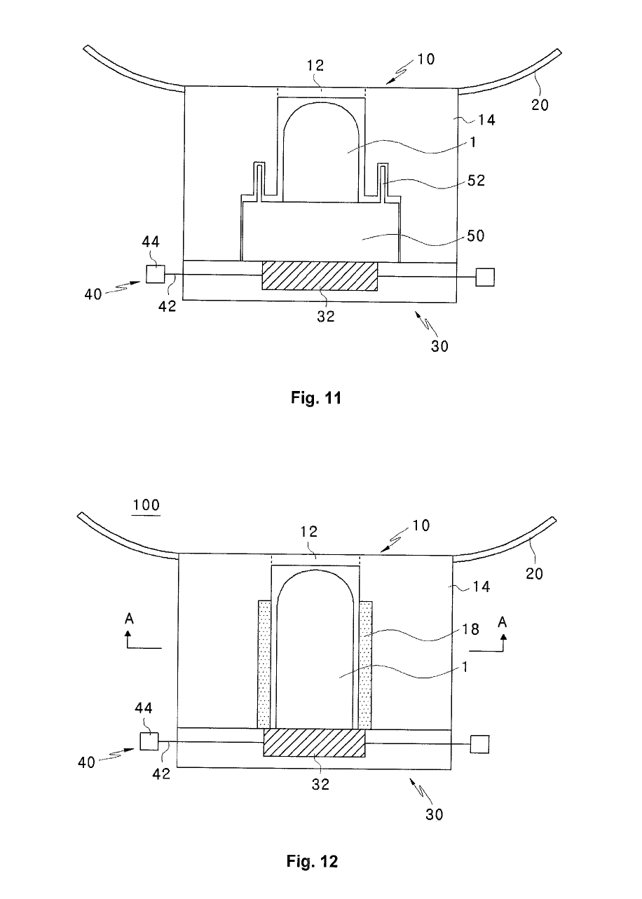

In the present invention, the air exhaustion means may be an air exhaustion groove 18 or embossing 19. FIG. 12 is a sectional view of the LED assembly having the adsorption plate having two air exhaustion grooves formed therein. FIG. 13 is a sectional view taken along line A-A of FIG. 12. As shown in FIGS. 12 and 13, at least one groove is formed in the insertion direction of the LED 1 at a part at which the inside of the light-permeable part 10 comes in contact with the LED 1. The air exhaustion groove 18 allows the air in the inside of the light-permeable part 10 to be exhausted to the outside in the process of inserting the LED 1 into the light-permeable part.

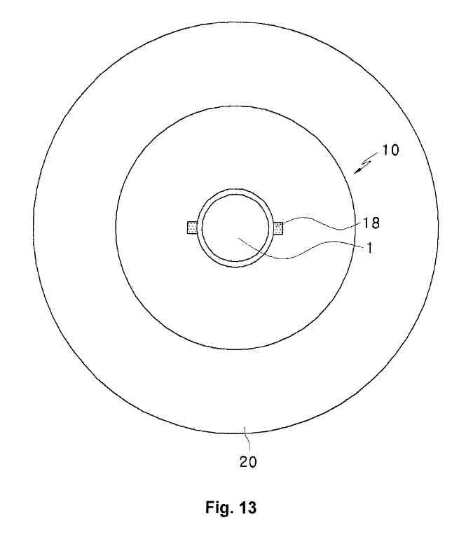

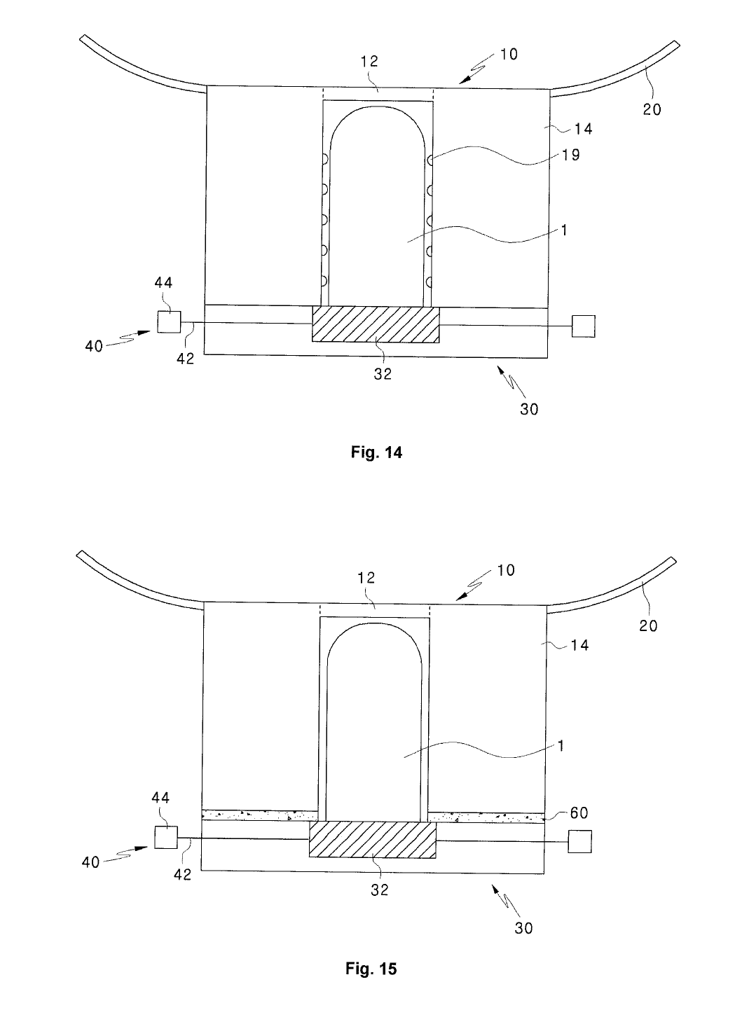

FIG. 14 is a sectional view of the LED assembly having an embossing form therein. As shown in FIG. 14, at least one embossing is formed at the part at which the inside of the light-permeable part 10 comes in contact with the LED 1. In the process of inserting the LED 1 into the light-permeable part, the air in the inside of the light-permeable part 10 is exhausted to the outside through a space between the embossings 19 so as to prevent excessive compressed air from being formed in the inside of the light-permeable part. Here, the air exhaustion groove 18 or embossing 19 may be formed not only at the side of the LED but also at the side of the support platform as occasion demands. In the LED assembly having the adsorption plate attached thereto according to the present invention, the adsorption plate 20 and the light-permeable part 10 are separated from each other, and the light-permeable part 10 may be coupled to the adsorption plate 20 by fitting the light-permeable part into the adsorption plate 20. A coupling means is not particularly limited. As shown in FIG. 24, a coupling part 22 capable of surrounding the outside of the light-permeable part 10 is provided to the adsorption plate 20, so that the light-permeable part 10 is fitted into the coupling part of the adsorption plate.

In the LED assembly having the adsorption plate attached thereto according to the present invention, a reflection plate 60 is formed on a bottom surface of the light-permeable part 10, so that light emitted from the LED is reflected to a front side of the LED, thereby increasing the advertisement effect. FIG. 15 is a sectional view of the LED assembly having the adsorption plate attached thereto, in which a reflection plate is mounted.

A power supply means of the LED assembly according to the present invention is not particularly limited, and may be one as long as it operates the LED. For example, the power supply means may be a battery (condenser), AC power source, DC power source, solar cell, hybrid, or the like.

In the LED assembly having the adsorption plate attached thereto according to the present invention, one LED assembly having an adsorption plate attached thereto may be used as described above. In most cases, characters or figures are expressed by combining a plurality of LED assemblies each having an adsorption plate attached thereto. Here, individual LED assemblies each having an adsorption plate attached thereto may be used to be connected to one another, but LED assemblies each having an adsorption plate attached thereto, which are previously connected to one another, may be sold.

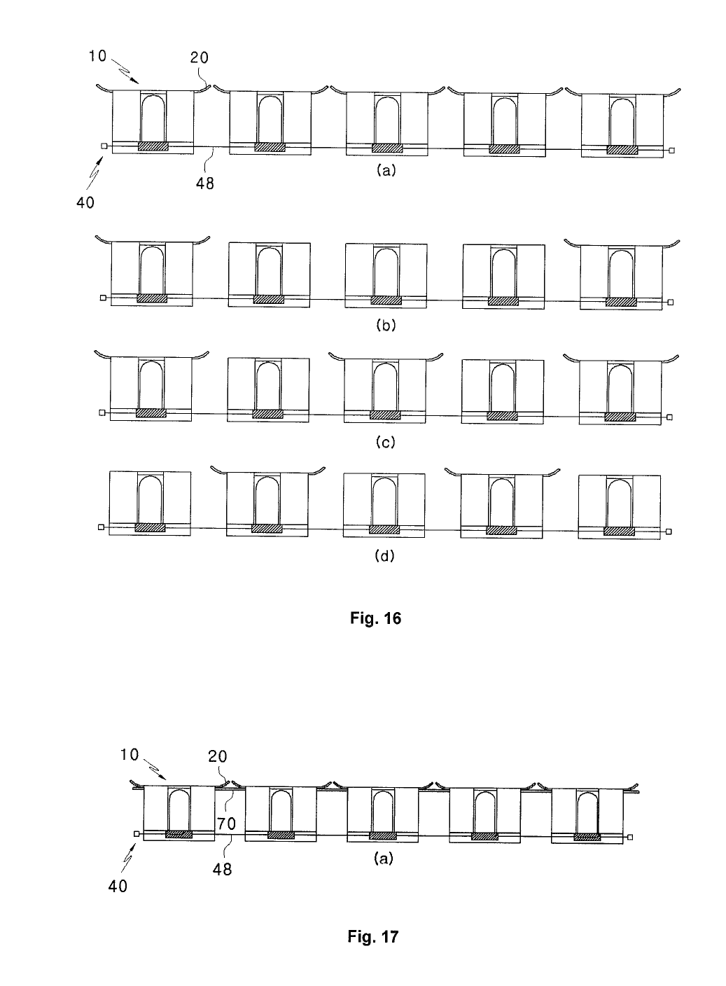

In this case, all the LED assemblies may have adsorption plates, or some of the LED assemblies may have adsorption plates. FIG. 16 shows embodiments in which five LED assemblies having adsorption plates attached thereto are combined. As shown in FIG. 16, the LED assemblies each having the adsorption plate attached thereto comprise at least one LED 1; light-permeable parts 10 each surrounding an emission part of the LED and transmitting light of the LED to the outside thereof, the light-permeable part having an opened lower part; caps 30 each positioned beneath the LED so as to surround the opened part of the light permeable part; connection parts 40 respectively connected to electric wires protruded from the caps at both ends of the LED assemblies; and connection wires 48 each protruded from the cap of an LED assembly positioned between the outermost LED assemblies and connected to the cap of an adjacent LED assembly. An adsorption plate 20 for fixing the LED assemblies to a fixture by being adhered closely to the fixture is attached to at least one light-permeable part. In a plurality of LED assemblies having adsorption plates attached thereto are connected to one another, all the LED assemblies may have the adsorption plates as shown in (a) of FIG. 16. However, some of the LED assemblies may have the adsorption plates 20 as shown in (b) to (d) of FIG. 16.

If the LED assemblies having the adsorption plates attached thereto are simply connected to one another by the connection wires 48, a user has difficulty in exactly attaching the LED assemblies on window so as to be suitable for a desired shape. Particularly, in a case where the LED assemblies are attached in a straight line on the window, the user pays careful attention to an attachment position when attaching one LED assembly having the adsorption plate attached thereto and then attaching the next LED assembly having the adsorption plate attached thereto. Accordingly, in the present invention, a plurality of LED assemblies each having an adsorption plate attached thereto may be fixed to an attachment plate 70. Here, the attachment plate 70 is preferably made of a material which is bent if a force to a certain degree or more is applied by the user and is not bent if a force to a certain degree or less is applied by the user. FIG. 17 is a schematic view of the plurality of LED assemblies each having the adsorption plate attached thereto, to which an attachment plate is mounted. As shown in FIG. 17, the plurality of LED assemblies each having the adsorption plate attached thereto are connected to the attachment plate. Here, the attachment plate 70 may connect the light-permeable parts 10 to one another, or may connect parts of the caps 30 to one another. It will be apparent that the attachment plate may connect other parts of the LED assemblies to one another.

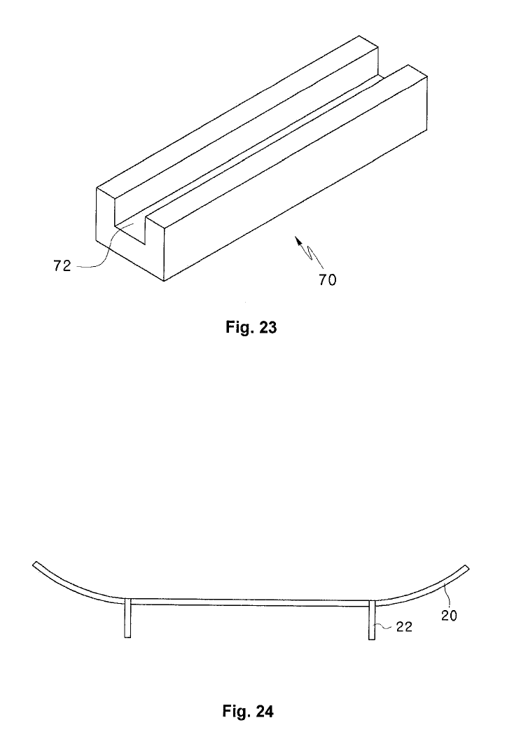

In a case where the attachment plate 70 connects the light-permeable parts 10 to one another as shown in FIG. 17, grooves are formed at a predetermined interval in the attachment plate 70, the LED assemblies each having the adsorption plate attached thereto are inserted into the grooves, respectively. In a case where the attachment plate 70 connects the caps 30 to one another, a protruding part is formed at the center of each of the caps 30, and the attachment plate 70 is formed in a ‘ [symbol] ’ shape so as to be coupled to the protruding parts of the caps 30, so that the caps are coupled to the attachment plate by inserting the protruding parts into the attachment plate. FIG. 23 is a schematic view of the ‘ [symbol] ’-shaped attachment plate 70. The cap 30 is formed to be inserted into a groove 72 of the attachment plate 70. In this case, the attachment plate 70 may be separated from the LED assemblies having each the adsorption plate attached thereto after the LED assemblies are attached to a fixture such as glass. The attachment plate helps the LED assemblies having each the adsorption plate attached thereto to be attached suitable for a desired shape.

FIG. 18 is a schematic view showing another embodiment of the LED assembly having the adsorption plate attached thereto according to the present invention. Unlike the aforementioned embodiment, the LED having the adsorption plate attached thereto is configured using two LEDs. As shown in FIG. 18, the LED assembly having the adsorption plate attached thereto according to this embodiment comprises first and second LEDs 1′ and 1″ respectively attached to both surfaces of a fixing part 35 about a fixing part 35; first and second light-permeable parts 10′ and 10″ for respectively surrounding the first and second LEDs and transmitting light of the first and second LEDs to outsides thereof; an adsorption plate 20 connected to the first light-permeable part at an edge of a top of the first light-permeable part and adhered closely to a fixture so as to fix the first light-permeable part to the fixture; and connection parts 40 protruded from the fixing part 35. Here, the fixing part corresponds to the cap of the aforementioned embodiment.

In FIG. 18, left-side and right-side parts X and Y of the LED assembly have the same shape when being viewed in the direction of the adsorption plate. However, the shapes of the left-side and right-side parts may be different from each other. For example, the left-side part X may have a hemispherical shape, and the right-side part Y may have a star shape.

A method of expressing characters or figures using the LED assemblies each having the adsorption plate attached thereto according to the present invention will be described. Characters or figures can be expressed by various methods using the LED assemblies each having the adsorption plate attached thereto according to the present invention.

For example, in a case where a user expresses a character ‘ [symbol] ’, 1) the character ‘ [symbol] ’ may be expressed by directly attaching the LED assemblies to a fixture such as window so that the LED assemblies can form the shape of the character ‘ [symbol] ’, 2) the character ‘ [symbol] ’ may be expressed by making grooves at a predetermined interval in cloth, film or paper on which the character ‘ [symbol] ’ is printed, respectively inserting the LED assemblies into the grooves and then attaching the LED assemblies to a fixture such as window, and 3) the character ‘ [symbol] ’ may be expressed by attaching an UV protection film formed in the shape of the character ‘ [symbol] ’ to a fixture such as window and attaching the LED assemblies at a predetermined interval on the UV protection film.

FIG. 19 is a view showing a state that ‘ [symbol] ’ is expressed by the LED assemblies each having the adsorption plate attached thereto according to the present invention. In FIG. 19, the LED assemblies 100 each having the adsorption plate attached thereto are attached at a predetermined interval to an UV protection film 120 on which the character ‘ [symbol] ’ is printed on window. Here, each of the parts ‘ [symbol] ’ and ‘ [symbol] ’ is expressed using the LED assemblies shown in FIG. 17, and an additional connection wire 130 having connection jacks 132 is connected between the parts ‘ [symbol] ’ and ‘ [symbol] ’. A connection part 40 is extracted from the other end of each of the parts ‘ [symbol] ’ and ‘ [symbol] ’, so that the LED assemblies can be connected to other LED assemblies or an external power supply.

The character ‘ [symbol] ’ can be recognized by the UV protection film 120, and its visibility can be more improved by the LED assemblies attached to the UV protection film. Particularly, information can be transmitted up to a long distance by bright light from the light-permeable thin part, and contents can be easily recognized even at a side thereof by dim light transmitted the side from the light-permeable thick part. Further, the blur of light, caused by window, can be minimized by the light-permeable part. Since the visual effect is considerably accomplished by combination of the light-permeable thin and thick parts, the visibility at long/short distances and front/sides can be entirely improved.

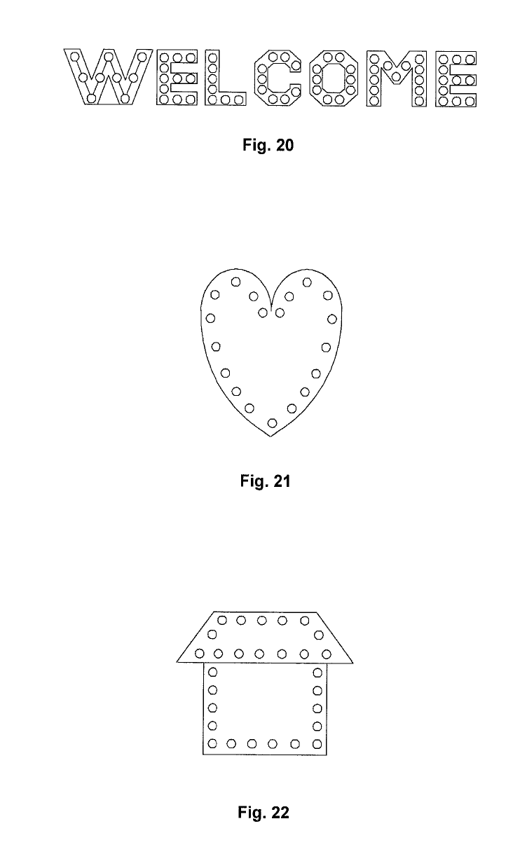

FIGS. 20 to 22 are views showing states that different characters or figures are expressed. In these figures, connection wires are omitted.

In the description of the present invention, the present invention has been mainly applied to window in a shop. However, the present invention may be applied to all places in which a flat fixture made of a transparent or translucent material such as glass is used. For example, the fixture may be glass of an automobile, mirror, and the like.

### INDUSTRIAL APPLICABILITY

The LED assembly having the adsorption plate attached thereto according to the present invention can be variously used for advertisements, displays, interior designs, and the like.

Although the present invention has been described in detail in connection with the specific embodiments, it will be readily understood by those skilled in the art that various modifications and changes can be made thereto within the technical spirit and scope of the present invention. It is also apparent that the modifications and changes fall within the scope of the present invention defined by the appended claims.

1. A light emitting diode (LED) assembly having an adsorption plate attached thereto, the LED assembly comprising:
at least one LED;
a light-permeable part configured to be connected to a sidewall of the LED and surround an emission part of the LED for transmitting light of the LED to an outside thereof;
the adsorption plate connected to the light-permeable part at an upper part of the light-permeable part and adhered closely to a fixture so as to fix the light-permeable part to the fixture;
a cap positioned on a bottom surface of the LED, the cap surrounding a lower portion of the light-permeable part; and
a connection part protruded from the cap,
wherein the light-permeable part comprises at least one light-permeable thin part of which thickness is thin in the light-permeable part so as to ease the glare of intense light just in front of the LED and to improve visibility at a long distance, and at least one light-permeable thick part of which thickness is thicker than that of the light-permeable thin part in the light permeable part so as to emit the light to sides of the LED by widely diffusing the light of the LED,
the light-permeable thin or thick part has the shape of a figure, number or character,
the thickness of the light-permeable thin part is 0.1 to 10 mm and
the light-permeable thick part is 1.5 to 20 times thicker than the light-permeable thin part.

2. The LED assembly of claim 1, wherein the connection part is composed of a flexible connection wire and a connection jack.

3. The LED assembly of claim 1, wherein the connection part is a connection port fixed to the cap.

4-7. (canceled)

8. The LED assembly of claim 5, wherein the light-permeable thin or thick part is made through combination of at least one of transparent, translucent and opaque materials.

9. The LED assembly of claim 1, further comprising a support platform positioned beneath the LED and adhered closely to a side of the light-permeable part.

10-12. (canceled)

13. The LED assembly of claim 1, wherein a diffusion layer is additionally attached at a lower part of the light-permeable part facing the top of the LED.

14. (canceled)

15. The LED assembly of claim 1, wherein at least one air exhaustion groove or embossing is formed at the side surface of the light-permeable part.

16. The LED assembly of claim 1, wherein the adsorption plate and the light-permeable part are separated from each other, and the light-permeable part is coupled to the adsorption plate.

17-18. (canceled)

19. A plurality of LED assemblies having adsorption plates attached thereto combined with one another so as to express a character or figure, wherein the LED assemblies comprises:
at least one LED;
light-permeable parts each surrounding an emission part of the LED and transmitting light of the LED to the outside thereof;
caps each positioned on a bottom surface the LED so as to surround an opened part of the light permeable part;
connection parts respectively protruded from the caps positioned at both ends of the LED assemblies; and
connection wires each protruded from the cap of an LED assembly and connected to the cap of an adjacent LED assembly so as to connect the plurality of LED assemblies to one another,
wherein the adsorption plate connected to the light-permeable part at an upper part of the light-permeable part and adhered closely to a fixture so as to fix the LED assemblies to the fixture is attached to at least one of the light-permeable parts.

20. The LED assemblies of claim 19, wherein the LED assemblies having the adsorption plates attached thereto are attached at a predetermined interval to the fixture.

21-24. (canceled)
